(19) United States
(12) Patent Application Publication
(10) Pub. No.: US 2014/0335320 A1
(43) Pub. Date: Nov. 13, 2014

(54) HIGH GLOSS MOLDING SHEET HAVING METALLIC EFFECT USING ULTRAVIOLET CURABLE RESIN LAYER AND A METHOD FOR MANUFACTURING THE SAME

(71) Applicant: LG HAUSYS. LTD, Seoul (KR)

(72) Inventors: Jun Beom Shin, Suwon-si (KR); Jae Gwang Nam, Busan (KR); Min Ho Lee, Busan (KR); Jung Eun Ha, Gimhae-si (KR)

(21) Appl. No.: 14/362,291

(22) PCT Filed: Sep. 12, 2012
(86) PCT No.: PCT/KR2012/007320

§ 371 Date: Jun. 2, 2014

(30) Foreign Application Priority Data
Dec. 28, 2011 (KR) 10-2011-0144912

(51) Int. Cl. B44F 1/02; B44F 1/10; B32B 7/12; C23C 14/34; B32B 15/08; B32B 3/30; C23C 14/24; B32B 38/06

(52) U.S. Cl. CPC B44F 1/02; C23C 14/24; B44F 1/10; B32B 38/06; C23C 14/34; B32B 15/08; B32B 3/30; B32B 7/12; B32B 2250/02; B32B 2255/06; B32B 2255/10; B32B 2255/205; B32B 2255/26; B32B 2305/77; B32B 2307/406; B32B 2307/412; B32B 2451/00
USPC 428/172; 156/220; 204/192.1

(57) ABSTRACT

The present invention relates to a high glossy molding sheet and a method for manufacturing the same that may realize a same outer appearance with an actual metal surface by forming a reverse pattern with an opposite shape to an original pattern of a metal board using a transfer of an ultraviolet curable resin layer, and forming a metal deposition layer on the top and laminating on a board.

### TECHNICAL FIELD

The present invention relates to a high glossy molding sheet having metallic effect using ultraviolet curable resin layer and a method for manufacturing the same that may realize the same outer appearance as an actual metal surface by forming a reverse pattern on an ultraviolet curable resin layer with an opposite shape to an original pattern of a metal board using transfer, and forming a metal deposition layer on the top to be laminated to a board.

### BACKGROUND ART

In prior sheets, hairline processed PETs are normally used to give similar feel as metal surface textures, but since only continuous hairlines may be technically created for hairline process formed on PETs, realizable design is very limited, and thus realizing excellent outer appearance close to an actual natural metal material having an irregular hairline was difficult.

Also, for manufacturing prior sheets, PVC films are used for most base layers, and this is because adhesive power of PVC films is excellent when adhering to cold-rolled steel sheets, plated steel sheets, etc., in which sheets are widely used through adhesives in construction material or consumer electronics products, and has low costs.

But PVC films emit a great amount of dioxins when incinerated, and dioxin is a material regulated as a hereditable 1^{st} degree carcinogen by the World Health Organization (WHO) in 1992, and is a colorless carcinogen that brings about fatal results by being accumulated in human bodies even with a small intake. Therefore, regulations for PVC usage are being applied worldwide, and demand for environmental friendly material replacing PVC for high glossy sheets is growing.

Meanwhile, regarding manufacturing high glossy sheets having metallic effects, Korea laid-open patent No. 2006-78530 discloses high glossy sheets used by laminating with a steel plate and an aluminum plate, and provides high glossy sheets having metallic effects by forming a hairline pattern layer on a different surface of a PET film, on which an ultraviolet curing or a thermal curing resin layer is applied to one side, and sequentially forming a primer layer formed with polyester copolymers, an aluminum deposition layer, an urethane adhesive later, and a thermoplastic resin sheet.

Also, in Korea laid-open patent No. 2008-14269, a sheet, which is a high glossy sheet having a same outer appearance as that of a metal surface and used by laminating on a board, comprising a thermal or an ultraviolet curing resin and a PET film placed on a top most layer, an adhesive layer applied on a bottom surface of the PET film, an aluminum foil placed on a bottom surface of the adhesive layer, and a primer layer applied on a bottom surface of the aluminum foil is disclosed.

And, regarding molding sheets with emboss effects, in Korea laid-open patent No. 2009-96778, a molding sheet comprised of, from the top, an ultraviolet curable resin layer, a primer layer, a transparent film layer, a print layer, an adhesive layer, colored film layer, and a primer layer, and an emboss pattern is given to a surface, and a transparent film layer is formed as a polyester resin layer is disclosed.

But, continuous research regarding molded sheets that may give a variety of emboss patterns, printing, pearl effects, etc. while having metallic effects is required.

### DISCLOSURE

### Technical Problem

Accordingly, the present inventors, from research and efforts to develop a high glossy molding sheet that may reproduce metal processing effects or etching effects while having unique patterns, such as hairline or emboss patterns, of metal boards, completed the present invention by discovering that a high glossy sheet having effects of outer appearance of metal without pattern damage in high temperatures could be manufactured when applying ultraviolet curable resin coating solution on a metal board with an original pattern formed on a surface, and adhering a transparent film layer on top of that, and then manufacturing ultraviolet curable resin layer with a reverse pattern formed from irradiating ultraviolet rays, and forming a metal deposition layer. Therefore, an objective of the present invention is to provide a high glossy molding sheet usable for interior films having metallic effects attached to a metal board.

Also, another objective of the present invention is to provide a method for manufacturing the high glossy molding sheet by applying an ultraviolet curable resin coating solution on a metal board with an original pattern formed on a surface, adhering a transparent film layer on top of that, and then manufacturing an ultraviolet curable resin layer with a reverse pattern formed by irradiating ultraviolet rays.

### Technical Solution

To achieve the objective, the present invention provides a high glossy molding sheet comprising, from the top, a metal deposition layer, an ultraviolet curable resin layer, a transparent film layer, and an adhesive layer, and a pattern is formed on the transparent film layer.

Also, the present invention provides a method for manufacturing a high glossy molding sheet comprising: applying an ultraviolet curable resin coating solution on a metal board with an original pattern formed on a surface; adhering a transparent film layer on top of the applied coating solution; manufacturing an ultraviolet curable resin layer with a reverse pattern, which has an opposite pattern of an original pattern, formed by irradiating ultraviolet rays; and forming a metal deposition layer on the ultraviolet curable resin layer with a reverse pattern formed.

### Advantageous Effects

The high glossy sheet in accordance with the present invention may realize unique patterns of various metal boards such as hairline or emboss patterns on film surfaces by ultraviolet curing ultraviolet curable resin coating solutions, and transparent hologram pattern effects of a variety of diffused reflection effects and interior effects may be realized from minute and precise patterns. Also, hologram patterns, metal processing effects, and etching effects may be reproduced by forming a metal deposition layer such as aluminum, stainless steel, etc. on a transferred surface ultraviolet curable resin layer. And realizing delicate and precise 3-dimentional effects and metal outer appearance effects without pattern damage even in high temperatures is possible, different from products given simple thermal embossing, by giving various patterns by using ultraviolet curable resins.

### DESCRIPTION OF DRAWINGS

FIG. 1 is a drawing illustrating a molding sheet in accordance with an embodiment of the present invention.

FIG. 2 is a drawing illustrating a molding sheet in accordance with an embodiment of the present invention

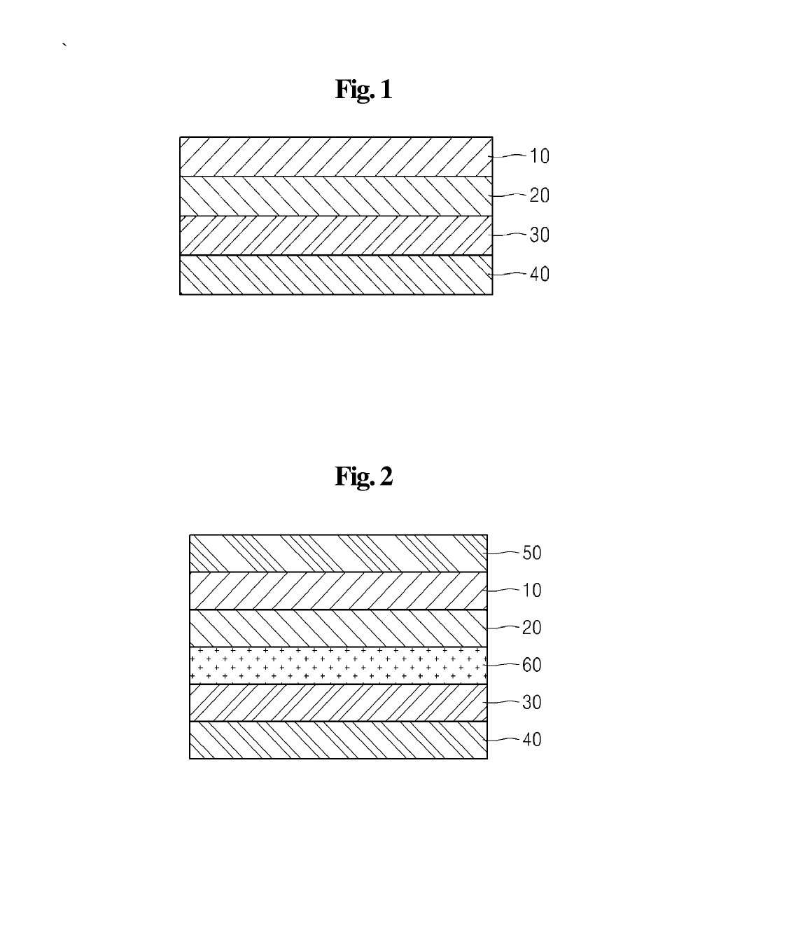

[Description of Symbols]

| | |
|---|---|
| 10: metal deposition layer | 20: ultraviolet curable resin layer |
| 30: transparent film layer | 40: adhesive layer |
| 50: surface protection layer | 60: primer layer |

### BEST MODE

Advantages and features of the present invention, and method for achieving thereof will be apparent with reference to the accompanying figures and detailed description that follows. But, it should be understood that the present invention is not limited to the following embodiments and may be embodied in different ways, and that the embodiments are given to provide complete disclosure of the invention and to provide thorough understanding of the invention to those skilled in the art, and the scope of the invention is limited only by the accompanying claims and equivalents thereof. Like components will be denoted by like reference numerals throughout the specification.

Hereinafter, a high glossy molding sheet in accordance with an embodiment of the present invention will be described in detail in reference with accompanying drawings.

High Glossy Molding Sheet

A high glossy molding sheet of the present invention comprises, from the top, a metal deposition layer (10), an ultraviolet curable resin layer (20), a transparent film layer (30), and an adhesive layer (40), and a pattern is formed on the transparent film layer (30).

In the present invention, a transparent film layer may use polyester resin, acrylic resin, urethane resin, olefin resin, etc., which are moldable by heat, but preferably, using polyester resin such as polyalkylene terephthalate resin is advantageous, and more preferably, using polyethylene terephthalate or polybutylene terephthalate is good.

It is preferable for a thickness of the transparent film layer to form 10˜100 μm, and more preferably to form 30˜50 μm.

Also, the ultraviolet curable resin layer may be formed from a coating solution comprising acrylic resin, its oligomer, and photo initiator, and may be cured from irradiating ultraviolet rays, and further, may further comprises additives such as pigments, etc.

For the acrylic monomer, acrylate or urethane acrylate, etc. having alkyl group of carbon number of 1˜12 may be used, and more specifically, there are butylacrylate, hexylacrylate, n-octylacrylate, isooctylacrylate, 2-etyl hexylacrylate, isononylacrylate, other (meth)acrylate monomer, etc., but is not limited to this.

Also, for photo initiators, radical initiators widely known to this field such as 2,2′-azobisisobutyronitrile (AIBN), benzoyl peroxide (BPO), etc. may be used.

A coating solution used for manufacturing the ultraviolet curable resin layer may use a resin solution of 30˜100% solid content, and it is preferable for the resin layer to be formed to 1˜50 μm.

Meanwhile, a primer layer may be formed between the ultraviolet curable resin layer and transparent film layer, and the primer layer takes the role of adhering ultraviolet curable resin on a transparent film layer, and acrylic, acrylurethane, epoxy, polyurethane, polyisocyanate, polyester, acrylate, ethylene-vinylacetate copolymer, polyamide, melamine, synthetic rubber, polyvinylalcohol resin, etc. may be used. It is preferable for the primer layer to be formed to 5 μm, and its thickness may be adjusted by changing solution viscosity of the resin.

The metal deposition layer is formed above the ultraviolet curable resin layer, and metal substance such as iron, nickel, chrome, copper, tin, or stainless steel may be deposited by common vacuum thermal deposition or sputtering methods, and it is preferable for the metal deposition layer to be formed in thickness of 100˜1000 nm.

And the adhesive layer may be formed by applying adhesives such as polyester, etc. in thickness of 10˜15 μm through a comma coater method, and a more distinct cubic effect may be displayed by being formed as an opaque layer. When an adhesive layer of the present layer is formed as an opaque layer, a pigment may be added.

Also, a surface protection layer may be formed on the metal deposition layer to protect a film surface from outside environments, and acrylic, acrylurethane, epoxy, polyurethane, polyisocyanate, polyester, acrylate, ethylene-vinylacetate copolymer, polyamide, melamine, synthetic rubber, polyvinylalcohol resin, etc. may be used.

A structure of a molding sheet further comprising the surface protection layer (50) and primer layer (60) is illustrated in FIG. 2.

Method for Manufacturing High Glossy Molding Sheet

A method for manufacturing a high glossy molding sheet of the present invention comprises:

applying an ultraviolet curable resin coating solution on a metal board with an original patterned formed on a surface;

adhering a transparent film layer on top of the applied coating solution;

manufacturing an ultraviolet curable resin layer with a reverse pattern, which has an opposite pattern of an original pattern, formed by irradiating ultraviolet rays;

and forming a metal deposition layer on the ultraviolet curable resin layer with a reverse pattern formed.

First, an ultraviolet curable resin coating solution is applied on a metal board with an original patterned formed on its surface. It is preferable for the ultraviolet curable resin coating solution to be applied at a thickness of about 1˜50 μm, and applying without adding solvents is more preferable to form the same pattern as the pattern formed on a mold such as an embossing roll.

Next, a transparent film is adhered to the coating solution, and acrylic, acrylurethane, epoxy, polyurethane, polyisocyanate, polyester, acrylate, ethylene-vinylacetate copolymer, polyamide, melamine, synthetic rubber, polyvinylalcohol resin, etc. may be used to adhere a transparent film layer.

In addition, when an ultraviolet ray is irradiated on a surface of a transparent film, a photo initiator in an ultraviolet curable resin coating solution activates, and a resin layer cures by radical polymerization among monomers. Upon this, a reverse pattern having an opposite pattern of the original pattern is formed on the surface of the ultraviolet curable resin layer in contact with a metal board.

After separating an ultraviolet curable resin layer, on which a reverse pattern formed, with the metal board, a metal deposition film is formed on the resin layer. Aluminum, iron, nickel, chrome, copper, tin, or stainless steel may be deposited by common vacuum thermal deposition or sputtering methods, and in the case of vacuum thermal deposition, vacuum deposition may be performed at 10⁻⁴˜10⁻⁶ torr and 300˜800° C., and in the case of a sputtering method, the metal deposition may be performed with a thickness of about 0.70 OD (Optical Density) by separating metal nano particles in a plasma state and coating the separated metal nano particles on the surface of the ultraviolet curable resin layer.

And then, an adhesive layer may be formed below the transparent film layer and a surface protection layer may be formed on the metal deposition layer, so that the molding sheet may be produced.

Hereinafter, a molding sheet of the present invention is described in detail through a preferred example of the present invention and a comparative example.

The example and comparative example below is for illustration only, and the scope of the present invention is not limited to the example.

### EXAMPLE

Acrylate resin solution comprising 10 parts by weight of 2,2′-azobisisobutyronitrile (AIBN) based on 100 parts by weight of urethaneacrylate as an ultraviolet curable resin coating solution is applied at a thickness of 10 μm on a surface of an aluminum board with a hairline pattern on its surface. Next, a polyethylene terephthalate film with a thickness of 38 μm is adhered to the coating solution, and an ultraviolet curable resin coating solution is cured by irradiating an ultraviolet ray with an amount of light of 400 mJ/cm².

When a resin layer is manufactured from the cured coating solution, a pattern formed on the surface of the resin layer is observed by separating an aluminum board. Next, an aluminum deposition layer with a thickness of 500 nm was formed by using a vacuum thermal deposition method at 10⁻⁵ torr and 500° C. on the resin layer. Next, a polyester adhesive layer was formed under a PET film by applying at a thickness of 12 μm by a comma coater method, and a molding sheet was manufactured by forming a surface protection layer on a metal deposition layer using acrylic resin.

Although embodiments in accordance with the present invention have been described herein, these embodiments are given by way of illustration only, and it should be understood that various modifications, variations and alterations can be made by those skilled in the arts. Therefore, the scope of the present invention should be defined by the appended claims.

1. A high glossy molding sheet comprising, from the top, a metal deposition layer, an ultraviolet curable resin layer, a transparent film layer, and an adhesive layer, and a pattern is formed on a surface of the transparent film layer.

2. A high glossy molding sheet according to claim 1, wherein the transparent film layer is a polyester resin layer.

3. A high glossy molding sheet according to claim 1, wherein the pattern is formed in a reverse pattern of an opposite shape from an original pattern of a metal board.

4. A high glossy molding sheet according to claim 1, wherein a primer layer is further comprised between the ultraviolet curable resin and transparent film layer.

5. A high glossy molding sheet according to claim 1, wherein a surface protection layer is further comprised above the metal deposition layer.

6. A high glossy molding sheet according to claim 1, wherein the transparent film layer is formed with a thickness of 10˜100 μm.

7. A method for manufacturing a high glossy molding sheet comprising:
applying an ultraviolet curable resin coating solution on a metal board with an original pattern formed on a surface;
adhering a transparent film layer on top of the applied coating solution;
manufacturing an ultraviolet curable resin layer with a reverse pattern having an opposite pattern of an original pattern formed by irradiating ultraviolet rays;
and forming a metal deposition layer on the ultraviolet curable resin layer with a reverse pattern formed.

8. A method for manufacturing a high glossy molding sheet according to claim 7, wherein the metal deposition layer is formed by a vacuum thermal deposition method or a sputtering method.
